(19) United States
(12) Patent Application Publication
(10) Pub. No.: US 2007/0248744 A1
(43) Pub. Date: Oct. 25, 2007

(54) Method for the determination of process parameters in a thermal spraying process

(75) Inventors: Torsten Wintergerste, Greifensee (CH); Marc Heggemann, Winterthur (CH)

Correspondence Address: HOGAN & HARTSON LLP;IP GROUP, COLUMBIA SQUARE, 555 THIRTEENTH STREET, N.W., WASHINGTON, DC, 20004, US

(73) Assignee: Sulzer Metco AG

(21) Appl. No.: 11/785,551

(22) Filed: Apr. 18, 2007

(30) Foreign Application Priority Data
Apr. 19, 2006 (EP) 06405169.1

(51) Int. Cl. B22D 23/00; C23C 16/52; B05D 1/08; B05B 5/025

(52) U.S. Cl. 427/8; 164/46; 427/446; 118/620

(57) ABSTRACT

A method is proposed for the determination of process parameters in a thermal spraying process, in which particles are melted or made plastic or vaporized by means of a thermal spraying apparatus (1) and are transported by a flow of fluid (G) to a substrate (6). In said method an operating model is constructed for the thermal spraying process or for the thermal spraying apparatus, with which a simulation of the thermal spraying process can be done and which includes a flow mechanical model and also an electromagnetic model, wherein the flow mechanical model and the electromagnetic model are coupled together and at least one process parameter is determined by means of the operating model.

### BACKGROUND OF THE INVENTION

1. Field of the Invention

The invention relates to a method for the determination of process parameters in a thermal spraying process.

2. Description of Related Art

Thermal spraying processes such as plasma spraying, for example, are used today for a large variety of coatings on completely different substrates. To this end an arc is created between an anode and a cathode in a plasma spraying apparatus such as a plasma burner. A gas is ionized between the electrodes, so that a plasma develops. The material required for the coating to be created is usually blown into the hot plasma in powder form, melted there or at least made plastic and applied to the substrate to be coated by the flow of gas at high speed.

Since the coatings to be generated are often of completely difference kinds, the thermal spraying process usually has to be adapted to the respective application. In this connection the result is often predetermined, such as the deposition rate, the layer thickness, the layer structure or other layer characteristics such as the porosity, the adhesion, the surface roughness, the electrical conductivity, the thermal conductivity, the viscosity, the resistance to wear, the proportion of the unmelted particles or chemical characteristics such as the degree of oxidation of the layer.

In addition to this it is also very important for industrial applications in particular that the spraying process per se has a high stability, producing reproducible results, and that it has a high processing and deposition efficiency.

In order to adapt the thermal spraying apparatuses to the respective application from the points of view named by way of example, it is desirable, if not indeed necessary, to have information on the process parameters such as gas speed and gas temperature, particle speed and particle temperature. Parameters of this kind can be recorded in principle using measurement technology, for example with the help of high speed cameras, however, measures of this kind are very complicated and expensive.

In view of the further development or new development of thermal spraying apparatuses, which generally takes place empirically nowadays, it is also desirable to have more information about the process parameters or to gain such information as simply as possible.

### SUMMARY OF THE INVENTION

It is thus an object of the invention to propose a method with which a most simple and yet reliable determination of process parameters is made possible under different operating conditions in a thermal spraying process. The method satisfying this object is characterized by the features of the claims.

In accordance with the invention, a method is therefore proposed for the determination of process parameters in a thermal spraying process, in which particles are melted or made plastic or vaporized by means of a thermal spraying apparatus and are transported by a flow of fluid to a substrate, wherein, in said method, an operating model is constructed for the thermal spraying process or for the thermal spraying apparatus, with which a simulation of the thermal spraying process can be done and which includes a flow mechanical model and also an electromagnetic model, wherein the flow mechanical model and the electromagnetic model are coupled together and at least one process parameter is determined by means of the operating model.

Due to the fact that the thermal spraying apparatus or the thermal spraying process is described by an operating model, the process parameters can be determined without a meteorological determination of the respective operating parameter being necessary. Since the operating model includes the coupling of a flow mechanical model with an electromagnetic model, in other words takes account of the mechanical—electromagnetic interactions e.g. between the flow of fluid and the arc, a reliable determination of the process parameters is made possible.

This operating model also allows pronouncements to be made about the process parameters in thermal spraying apparatuses, if these are working under extreme operating conditions. Thus loading limits for thermal spraying apparatus can, for example, be examined.

Furthermore the method in accordance with the invention can be applied particularly advantageously for further developments and new developments of thermal spraying apparatus. The entire spraying process or the spraying apparatus can, namely be simulated by the determination of the process parameters in accordance with the invention. This allows a considerably simpler and faster optimization of the design of the spraying apparatus or parts thereof, for example, of the nozzle.

The operating model preferably includes the interaction between the particles and the flow of fluid. By taking account of the particles brought into the flow of fluid in the operating model, the process parameters can be determined more exactly. Moreover, in this way, statements about the flight path of the particles or their speed become possible, for example.

The particles are regarded as stretched bodies during modeling. In an embodiment of the method the process parameters, which relate to a particle, for example the temperature of the particle, are assumed to be constant over the extent or the whole volume of the respective particle. This means, for example, that it is assumed that the particle has a homogeneous or uniform temperature, which naturally alters with its position in the flow of gas. In another embodiment variations of the process parameters concerning the extent of a particle are admitted during the modeling; this means, for example, that the temperature is no longer assumed to be constant over the extent of the particle.

At least one of the following process parameters is preferably determined: speed of the particles, temperature of the particles at the surface of the particles, temperature inside the particles, aggregate state of the particles, track of the particles, point of impact of the particles. A further advantageous measure is to compile a temperature profile for the particles.

Through knowledge of the temperature inside the particles or of the temperature profile it is, for example, possible to recognize whether the particles are also melted or made plastic in their interior. Such information is useful in order to monitor the characteristics of the coating to be produced.

For the same reasons it is advantageous to compile a speed profile or a temperature profile for the flow of fluid.

The method in accordance with the invention is also suitable in an advantageous manner for the optimization of spraying processes and spraying apparatus. Thus a desired value can be predetermined for at least one process parameter and the thermal spraying apparatus or the thermal spraying process can be optimized by means of the operating model, until the desired value is reached within pre-determinable limits. This permits an optimization, which is clearly faster than one purely based on empiric procedure.

In a preferred use, namely in the event that the thermal spraying apparatus includes a nozzle, through which the flow of fluid discharges, the operating model is used to optimize the nozzle.

The method in accordance with the invention is particularly suitable if the thermal spraying apparatus is a plasma spraying apparatus, in which an arc is produced between an anode and a cathode. The method in accordance with the invention is also particularly suitable for multiple cathode plasma burners.

An advantageous measure is determining the shape and/or the contact points of the arc by means of the operating model. The life of the spraying apparatus can thereby be extended, for example. Moreover, the stability of the arc can be examined under different operating conditions.

A thermal spraying apparatus, in particular a plasma spraying apparatus is further proposed by the invention, which is operated with the help of a method in accordance with the invention.

According to an especially preferred embodiment the flow mechanical model is a CFD model and the electromagnetic model is a model based upon the Maxwell equations, which is suited to describe the interacting electrical and magnetic effects in a quantitative manner.

A computer program product for the implementation of a method in accordance with the invention into a data processing unit is also proposed.

Further advantageous measures and preferred embodiments of the invention result from the dependent claims.

### BRIEF DESCRIPTION OF THE DRAWINGS

The invention will be explained in the following in more detail with reference to the embodiments and to the drawings. The schematic drawing shows:

FIG. 1 a schematic illustration of an embodiment of a thermal spraying apparatus, which is designed as a plasma spraying apparatus.

### DETAILED DESCRIPTION OF THE INVENTION

A method for the determination of process parameters in a thermal spraying process, in which particles are melted or made plastic by means of a thermal spraying apparatus and are transported by a flow of fluid, for example a flow of gas, to a substrate is proposed by the invention. The term “process parameters” refers to all parameters which in any way serve for the characterization of the operating state of a thermal spraying apparatus or the characterization of the thermal spraying process. Such process parameters are, for example, the speed or velocity field of the fluid, or the gas, the temperature or temperature profile of the fluid or of the gas, the speed of the particles (at different places), the temperature of the particles at the surface of or inside the particles, the aggregate state of the particles, the position or track of the particles, the disintegration or breaking up of particles, erosion, the contact points between an arc and the electrodes, the shape and extent of the arc, characteristic properties of the fluid or of the gas such as specific thermal capacity, degree of ionization. This list is not complete.

In the following reference will be made to an application which is particularly important for practical use, in which the thermal spraying process is a plasma spraying process and the spraying apparatus is a plasma spraying apparatus. The invention is naturally not limited to such applications, but is also suitable for other thermal spraying methods such as radio frequency (RF) plasma spraying for example or arc wire spraying.

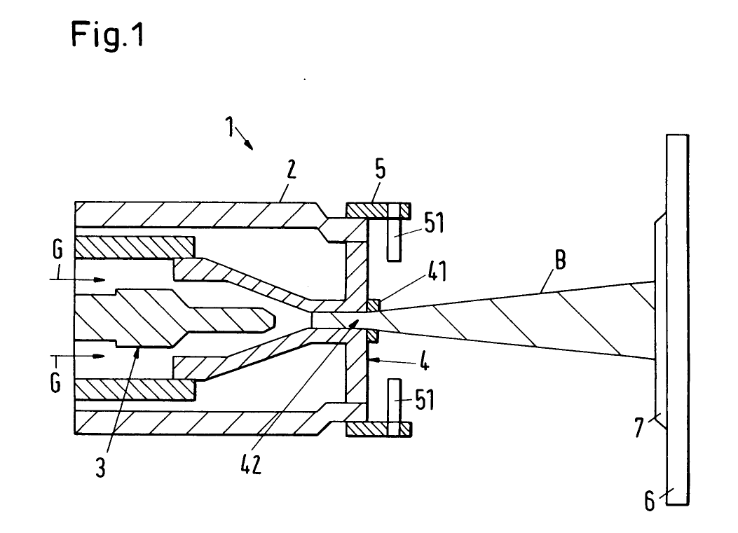

FIG. 1 shows in a very schematic illustration an embodiment of a plasma spraying apparatus, which is referred to as a whole with the reference numeral 1. The plasma spraying apparatus 1 includes a housing 2, in which a cathode arrangement 3 and an anode 4 electrically insulated from this are provided. The anode 4 is designed here as a ring anode, which has an outlet opening 42 in its centre, which is provided with a nozzle 41. During operation a gas is blown through the plasma spraying apparatus 1 in the axial direction as is indicated by the two arrows with the reference symbol G. A powder supply 5 is provided behind the circular anode 4 viewed in the flow direction, which has one or more supply channels 51, which extend substantially in an axial direction. It is naturally also possible that the supply channels 51 for the powder or for the particles extend in an axial direction or obliquely, in other words extend between the axial and the radial direction.

Further components known per se of the plasma spraying apparatus such as the cooling, the energy supply, and the control apparatus have not been illustrated for reasons of a better overview.

The plasma spraying apparatus 1 can, in particular, also be a multiple cathode burner, such as the burner for example, which is marketed by the inventor under the trade name TriplexPro. In this burner the cathode arrangement 3 includes three cathodes in total. Three arcs then arise in the operating state.

During operation, the gas G flowing in the axial direction through the plasma spraying apparatus 1 is ionised and at least one arc is produced between the cathode arrangement 3 and the anode 4. The gas G heated by the plasma emerges through the nozzle 41 out of the anode at high speed and at high temperature. Directly behind the anode 4 (seen in the flow direction of the gas) particles in the form of a powder are blown through the supply channels 51 of the powder supply 5 into the hot flow of gas. The particles are melted or at least made plastic in the flow of gas, accelerated by the flow of gas and thrown onto a substrate 6 where they form a coating 7. The flow of gas loaded with the particles is illustrated schematically in FIG. 1 as coating beam B.

It is often the case in use that the result to be achieved—in other words the coating 7 on the substrate 6 or its characteristics—are predetermined and that the thermal spraying process is to be adjusted in such a way that the desired result is realized as well, as efficiently, as economically and as reproducibly as possible. To this end it is important to know the process parameters.

A method for the determination of process parameters is proposed by the invention, in which an operating model is constructed, which includes a flow mechanical model and also an electromagnetic model coupled to this and by means of this operating model one or more process parameters are determined.

It has been shown that a reliable determination of the process parameters is made possible by taking account of flow mechanical effects as well as the electromagnetic and/or electro-dynamic effects.

Since a meteorological determination of the process parameters is thus no longer necessary, but the spraying process can rather be simulated, the behaviour of the thermal spraying apparatus can now also be analyzed in such operating conditions, which have not yet been examined. Moreover, it is possible to determine process parameters which could, up to now, only be determined with great difficulty or not at all using meteorological technology, for example those of particles (especially in their interior).

In the following an embodiment of the method in accordance with the invention will now be explained.

The flow mechanical modeling preferably takes place by means of numeric flow stimulation (CFD—Computational Fluid Dynamics). The CFD method has developed into a very efficient tool for the examination of flows in recent years. CFD and its basics per se are known to the person averagely skilled in that art and thus do not need to be explained more closely here.

The three fundamental principles of the conservation of mass, momentum and energy apply for each flow. The physical relationships and equations (the Navier Stokes equations) resulting from this can no longer be analytically solved in their general form however. It is the subject matter of the CFD, to determine numerical solutions for equations of this sort in order to describe a flow field as realistically as possible. The Navier Stokes equations contain the variables describing the flow as velocity, pressure, density and temperature as a function of place and time.

Within the context of this application, CFD is understood as the method of calculating friction-free and frictional flows of single phase or multi-phase fluids (continuous phase), if necessary taking simultaneous account of the movement of fluid drops or solid particles (disperse phase). The fluids can be compressible or incompressible. The interaction or cooperation of the continuous phase with the disperse phase can be described with the Lagrange-Euler model and also with the Euler-Euler model. The exchange of mass, impulse and energy can either be observed in one direction (from the continuous to the discrete phase or rather one-way coupling or vice versa) or in both directions (complete coupling or two-way coupling).

This not only refers to those CFD methods in which the disperse phase is included in the model but also to CFD methods in which the disperse phase is not included in the model. This means that the particles do not automatically have to be taken into consideration in the model. However, the operating model preferably also includes the particles and the interaction between the particles and the flow of gas.

Not only the continuous phase, but also the discrete phase can each contain a plurality of components (multi-component phase). During plasma spraying a mixture of argon and helium can be used, for example; then the continuous gas phase includes the two components argon and helium. The discrete phase can also contain a plurality of components, if for example a powder mixture of different substances is used as particles in plasma spraying or if already melted and still solid particles form two components of the discrete phase.

There are numerous computer program products and algorithms for CFD known per se and commercially available which are sufficiently known to the person averagely skilled in the art, so that this does not have to be gone into further.

In the flow mechanical modeling the flow space to be calculated is initially defined as a three-dimensional volume body, for example by means of a CAD model of the spraying apparatus. Then small finite sub volumes are defined, into which the volume body is divided.

These sub volumes form the numerical calculation grid. The boundary conditions are laid down, which define the physical operating conditions, for example mass flows or flow rates on entry, the temperature of the gas on entry, the temperature at the walls, flow strength or similar. Then the flow parameters such as pressure, speed or temperature in each sub-volume is determined using numerical procedures known per se. The results lead to a three-dimensional flow field, which is then evaluated quantitatively and qualitatively.

Due to the extremely high temperatures during plasma spraying—the plasma can for example reach temperatures of up to 19,000° Kelvin—the temperature dependency and/or the pressure dependency of the material characteristics are taken into consideration. With respect to the continuous phase, here the gas phase, the temperature and/or pressure dependency of the following dimensions in particular is taken into consideration: electrical conductivity, thermal conductivity, viscosity, specific thermal capacity, electron density, molar mass, ion concentration for the different ionization stages, velocity of sound. These dependencies are known or can be calculated in a manner known per se.

It can be sufficient, for some process dimensions or qualitative statements or first approaches in optimizing processes for example, if one does not take account of the particles blown into the flow of gas during plasma spraying in the flow mechanical modeling. The particles are preferably taken account of as the disperse phase in the operating model, however.

According to the invention, the flow mechanical model is coupled to an electromagnetic model. The at least one arc produced between the cathode arrangement 3 and the anode 4 in the plasma spraying apparatus 1 heats and accelerates the gas G. The coupling between the flow mechanical and electromagnetic model permits the description of the arc or arcs. The arc or the plasma in turn cause electromagnetic effects such as electric potentials, magnetic fields etc., the influence of which are taken into consideration by the electromagnetic model or rather its coupling to the flow mechanical model.

Boundary conditions are also laid down for the electromagnetic characteristics, in particular for the electric potential and for the magnetic vector potential. It can be assumed, for example, for the electric potential that the cathode arrangement 3 lies at earth potential, i.e. zero volts and the potential of the anode is controlled in such a manner that the pre-determined current flows.

The electromagnetic model is based on the Maxwell equations and on the material characteristics for the polarization (dielectric constant), the magnetization (permeability) and the conductivity.

The coupling between the flow mechanical model and the electromagnetic model takes place via Ohm's Law, via the Lorentz force (force on moving charge carriers in the magnetic field) and the resistive heating. In this connection the Lorentz force couples the electromagnetic effects to the fluid dynamics while the resistive heating couples the electromagnetic effects to the thermodynamic energy equations.

The solution of the resulting equations usually takes place numerically. The person averagely skilled in the art is sufficiently aware how such electromagnetic models per se are compiled and calculated. Computer program products are also known for this, so that no further explanations are necessary in relation to this.

From a technical programming viewpoint, the taking into consideration of the electromagnetic models can take place in the form of a program module (plug in) which is put into or integrated into the CFD program for the flow mechanical modeling.

A complete stimulation of the thermal spraying process is possible with the help of the operating model. This means in particular that each process parameter can be determined by means of the operating model.

A few applications will now be explained by way of example in the following.

Due to the fact that the whole thermal spraying process can be simulated by means of the operating model, it is possible to adapt the thermal spraying apparatus to the respective application considerably faster and more efficiently and to optimize it to the respective application. This is an important advantage in view of the new and further development of thermal spraying apparatus. Namely, no time-consuming and expensive series of tests are any longer necessary in which empirically motivated modifications are tested, but rather the influence of alterations on the process parameters can be examined with the help of the operating model without expenditure and/or effort for experiments.

The stability of the process is of great significance for industrial applications of thermal spraying, i.e. the same coating is to be produced with the same characteristics over a longer period of time. The method in accordance with the invention can be used here to identify the process dimensions essential for the process stability and to analyze the influence of its operationally caused fluctuations.

Since the efficiency of the spraying apparatus plays a substantial role from an economic viewpoint, the aim exists of operating such spraying apparatuses at the limit of their capabilities. The method in accordance with the invention is suitable for determining these limits more precisely.

Further essential aspects for industrial use in particular are a high application rate (how quickly can the coating be produced?), a high application efficiency (how much energy is required to apply a certain amount of coating material?) and a high working life of the apparatus and its components. The method in accordance with the invention is also suitable here to improve the operating behaviour of the spraying apparatus significantly in an efficient manner.

The method in accordance with the invention also forms a very useful tool for the optimization of the design with regard to new developments and further developments of spraying apparatuses.

It is often the case that the coating to be produced is specified by a customer for example, and that the spraying apparatus or the spraying method has to be adapted to these specifications.

Specifications of this type, for example, can be the nature and strength of the adherence or adhesion of the coating to the substrate, or other characteristics of the coating 7, such as, for example, the structure, the crystallinity, the texture, the thickness, the porosity, the roughness, the electrical or thermal conductivity, the viscosity, the resistance to wear or the degree of oxidation, to name only a few characteristics. In order to adjust such characteristics of the coating in a consciously intentional and controlled fashion, suitable process parameters have to be known.

This should be demonstrated on the basis of an example: in order to produce a pre-determined coating, it is necessary, for example, that the particles of a given size strike the substrate 6 at a desired temperature and at a desired speed. An optimization can now be carried out with the aid of the operating model, in which the adjustable process parameters, for example the current strength or the gas flow rate, are varied until the desired value for the temperature and the speed of the particles on impact on the substrate is reached within specifiable limits.

It is alternatively also possible to initially determine which speed and temperature profile the flow of gas has to have, in order for the particles to be heated up to the desired temperature and to be accelerated to the desired speed. Subsequently the parameters which can be influenced are varied until these profiles result for the flow of gas. In this connection it is also possible, particularly in new developments and further developments of spraying apparatuses, to vary and optimize the geometry of the spraying apparatus as a parameter.

If the optimization takes place by means of the determination of the profiles of the flow of gas, it can be advantageous for reasons of efficiency, if one initially determines some possible optimum variants, for example for the geometry of the spraying apparatus, by not taking the particles into consideration in the operating model. When a few possible designs or parameter combinations are then calculated, the refinement and finally the optimization takes place by means of an operating model in which the particles and if necessary also the substrate have been taken into consideration.

Further process parameters, which can be determined using the method in accordance with the invention and knowledge of which is advantageous, are the aggregate state of the particles, the track, i.e. the flight path of the particles, the point of impact of the particles on the substrate.

It is also advantageous to determine the velocity field or the speed profile of the flow of gas. With the help of this, an optimization of the flow ratios in the spraying apparatus can be attained.

It is further advantageous to know the temperature profile of the flow of gas. Thus irregularities in the temperature distribution, so-called hot spots, can be localized, for example.

Thus it is possible, for example, to produce a thermal or a thermodynamic image of the spraying apparatus. Using this, the course of the cooling channels can then be optimized in such a way that precisely so much heat is dissipated that the temperature of the internal surfaces remains within predetermined limits, in order to avoid erosion and other undesired effects.

Knowing the track or the flight path of the particles, permits the intentional influencing of the quality of the coating, for example, (porosity, adherence etc) because it is known that these characteristics of the coating depend on the angle at which the particles strike the substrate.

The shape and the extent of the arc or the arcs and the associated spots on the electrodes 3, 4 can be determined using the method in accordance with the invention. The stability of the arc or the arcs can be optimized using this knowledge, so that, for example, a uniform and predictable heating of the flow of gas results.

If one not only considers the particles as extended images with a certain diameter or a certain extent, but rather as extended bodies with varying process parameters in the operating model, then, in the method in accordance with the invention, not only the temperature at the surface, but also the temperature inside the particles can be calculated. A temperature profile for the particles can also be compiled. Particularly the temperature inside the particles constitutes a parameter, the knowledge of which is of great interest and which cannot, however, as yet be determined using measurement technology. The meteorological determination is limited to the temperature at the surface of the particles. In order to influence the coating intentionally, it is, however, advantageous to know the temperature inside the particles because it is frequently the case that the particles may be melted on their surfaces but are still solid and “cold” inside. This leads to a high proportion of unmelted regions in the coating, which are usually undesirable.

It is further possible to determine the temperature at the surface of the substrate 6 by means of the method in accordance with the invention. This is advantageous because in some applications the substrate is not allowed to be heated up too far, or because a certain temperature range is required at the substrate surface in order to achieve the predetermined characteristics of the coating.

The method in accordance with the invention is also particularly suitable to optimize the nozzle 41 in a thermal spraying apparatus 1, in particular in a plasma spraying apparatus and in particular its geometry. The nozzle 41 is a replacement part, i.e. different nozzles 41 with different geometries and correspondingly different flow characteristics are used depending on the application. If, for example, a nozzle 41 with a large opening is used, then the plasma is very hot and the speed of the emerging flow of gas is lower. With a smaller nozzle aperture the flow of gas is somewhat cooler, but has a higher speed. For the production of colder high speed flows convergent-divergent nozzles are used for example, which are designed similar to a Laval nozzle. The method in accordance with the invention now permits the optimizing of the design of the nozzle 41 such that it realizes the pre-determined process parameters for the emerging flow of fluid or gas as well as possible.

The method in accordance with the invention is also suitable to operate a thermal spraying apparatus, in particular a plasma spraying apparatus 1. In this connection the operating model can serve to record and store pre-determined process parameters during operation, which are, for example, not directly measurable or the operating model can be integrated into the control or regulation of the spraying apparatus in order to regulate one or more process parameters to a desired value.

The method in accordance with the invention is further suitable for the development and/or the carrying out of hybrid processes, in which thermal spraying is combined with other processes, for example for a hybrid process cold gas spraying/plasma spraying.

The method in accordance with the invention is preferably implemented in a data processing unit in the form of a computer program product.

A method is proposed for the determination of process parameters in a thermal spraying process, in which particles are melted or made plastic by means of a thermal spraying apparatus (1) and are transported by a flow of fluid (G) to a substrate (6), wherein, in said method, an operating model is constructed for the thermal spraying process or for the thermal spraying apparatus, which includes a flow mechanical model and also an electromagnetic model, wherein the flow mechanical model and the electromagnetic model are coupled together and at least one process parameter is determined by means of the operating model.

1. A method for the determination of process parameters in a thermal spraying process, in which particles are melted or made plastic or vaporized by means of a thermal spraying apparatus and are transported by a flow of fluid to a substrate, wherein, in said method, an operating model is constructed for the thermal spraying process or for the thermal spraying apparatus, with which a simulation of the thermal spraying process can be done and which includes a flow mechanical model and also an electromagnetic model, wherein the flow mechanical model and the electromagnetic model are coupled together and at least one process parameter is determined by means of the operating model.

2. A method in accordance with claim 1, in which the operating model includes the interaction between the particles and the flow of fluid.

3. A method in accordance with claim 1, in which at least one of the following process parameters is determined: speed of the particles, temperature of the particles at the surface of the particles, temperature inside the particles, aggregate state of the particles, track of the particles, point of impact of the particles.

4. A method in accordance with claim 1, in which a temperature profile is generated for the particles.

5. A method in accordance with claim 1, in which a speed profile or a temperature profile is generated for the flow of fluid.

6. A method in accordance with claim 1, in which a desired value is specified for at least one process parameter and the thermal spraying apparatus or the thermal spraying process is optimized by means of the operating model, until the desired value is reached within specifiable limits,

7. A method in accordance with claim 1, in which the thermal spraying apparatus includes a nozzle through which the flow of fluid emerges, wherein the operating model is used to optimize the nozzle.

8. A method in accordance with claim 1, in which the thermal spraying apparatus is a plasma spraying apparatus, in which at least one arc is produced between an anode and a cathode arrangement.

9. A method in accordance with claim 8 in which the shape and/or the contact points of the arc are determined by means of the operating model.

10. A thermal spraying apparatus, in particular a plasma spraying apparatus, which is operated with the aid of a method in accordance with claim 1.

11. A computer program product for the implementation of a method in accordance with claim 1 in a data processing unit.
